(19) United States
(12) Patent Application Publication
(10) Pub. No.: US 2026/0314300 A1
(43) Pub. Date: Oct. 8, 2026

(54) TRANSFER STAMP AND METHOD FOR MANUFACTURING A TRANSFER STAMP

(71) Applicant: ams-OSRAM International GmbH, Regensburg (DE)

(72) Inventor: Tobias Berthold, Wenzenbach (DE)

(21) Appl. No.: 19/108,357

(22) PCT Filed: Sep. 4, 2023
(86) PCT No.: PCT/EP2023/074190

§ 371 Date: Mar. 3, 2025

(30) Foreign Application Priority Data
Sep. 5, 2022 (DE) 10 2022 122 478.3

(51) Int. Cl. H10P 72/00

(52) U.S. Cl. CPC H10P 72/0442

(57) ABSTRACT

In an embodiment a transfer stamp includes a plurality of stamp bodies, each having a height and a stamp surface with an edge length, wherein a ratio of the height to the edge length is greater than 1.3, a stabilizing layer of a material different from the stamp body on sides of the stamp body, wherein the stamp surface remains substantially free of the material of the stabilizing layer, and wherein the material of the stabilizing layer has a greater stiffness than a material of the stamp body and a plurality of support bodies, each support body adjoining one of the stamp bodies in a longitudinal direction, wherein the support body has a surface on which the stamp body is arranged, the surface being larger than the stamp surface.

### CROSS-REFERENCE TO RELATED APPLICATIONS

This patent application is a national phase filing under section 371 of PCT/EP 2023/074190, filed Sep. 4, 2023, which claims the priority of German patent application no. 10 2022 122 478.3, filed Sep. 5, 2022, each of which is incorporated herein by reference in its entirety.

### TECHNICAL FIELD

The present invention relates to a transfer stamp for transferring semiconductor components and to a method for manufacturing such a transfer stamp

### BACKGROUND

When transferring small (<20 μm) semiconductor components in parallel using a stamping process (e.g. with a structured silicone mat), the mechanical properties of the stamp elastomer give rise to various problems when removing and depositing the components. On the one hand, the stamp as such is designed with a certain stickiness, whereby the strength of this must be carefully selected.

Current transfer stamps consist of a material, usually PDMS or a silicone with a certain hardness and stickiness. The stickiness and hardness can already be using different material mixtures. However, the stickiness and hardness of PDMS cannot be changed completely independently.

When the semiconductor components are set down, they are often removed using a certain shear force, i.e. not only with a force acting perpendicular to the surface. The same applies at least in part to the pick-up process, although this can also take place without the use of shear forces. This means that certain dimensional tolerances and certain shapes are required for the stamp pad in order to be able to place semiconductor components as tightly as possible. The hardness or stiffness of an elastomer-based stamp generally poses a problem. Although a higher stiffness enables higher tolerances when transferring semiconductor components, especially with an edge length of less than 10 μm or even less than 5 μm, the shearing movement when depositing the components results in restrictive limit ranges for the dimensions of stamps in practice.

It has been found that for the stamp materials used to date—mainly elastomer-based processes—the stamps have a ratio of height to edge length of around 1, but in particular they cannot be larger, as otherwise the bending would be too strong. In addition, this method only achieves a low level of laydown force.

When transferring a large number of components at the same time, the required mechanical stability results in a certain minimum distance between two neighbouring stamps.

### SUMMARY

Embodiments overcomes at least some of the difficulties mentioned above, so that a simultaneous transfer of a larger quantity of components is possible.

The inventor proposes using an additional layer on the side surfaces of the actual stamp to stabilize it mechanically, particularly against further shear forces. In contrast, the contact surface required for the transfer remains unchanged. This has the advantage of achieving various effects. On the one hand, different interconnect materials can be used, including those that require increased discard forces. The additional stabilization also makes it possible to change the ratio of the height of the die to the edge length in favour of the height. Put simply, the stabilization makes longer stamps possible. Accordingly, the density of the transfer stamps can be increased according to the proposed principle, so that more components can be transferred at the same time.

According to the proposed principle, components with a size between 1 μm and 5 μm can be transferred without having to carry out a complex optimization of the machine accuracies. Other substrates or panels can be used that could not previously be used due to the tight height tolerances.

In some aspects, a transfer stamp for transferring an optoelectronic component comprises one or more stamp bodies having a height and a stamp surface with an edge length, wherein a ratio of the height to the edge length is greater than 1.2 and in particular greater than 2. The stamp is thus significantly longer than its corresponding edge length, the ratio can therefore be between 1.5 and 5 in particular. In some aspects, it is greater than 2 and is between 2.5 and 4.5.

According to the proposed principle, a stabilizing layer made of a material different from the stamp bodies is applied to the sides of the stamp bodies, with the stamp surfaces remaining essentially free of the material. The material of the stabilizing layer has a greater rigidity than a material of the stamp bodies. In this context, a material different from the stamp body is understood to mean a material which is either fundamentally different from the material of the stamp body, but also a material which is produced from the material of the stamp body by chemical or physical reaction (e.g. temperature or pressure or plasma treatment).

The proposed principle thus creates a transfer stamp in which the shearing movement reduces the adhesive force between the stamp and the component to be transferred, thus enabling the components to be reliably deposited on the recipient surface. In addition to a higher transfer yield, shorter process times are achieved. Furthermore, additional lines of freedom or a larger process parameter space are possible with different receiver surfaces. In addition, it was surprisingly found that the stickiness along the side surfaces is drastically reduced due to the stabilizing layer. In the event of a slight misalignment, this leads to significantly reduced tilting of the components to be transferred, thus increasing the placement tolerances and yield.

In some aspects, the transfer stamp according to the proposed principle comprises a support body adjoining the stamp body in the longitudinal direction. In some aspects, this can merge into a wider base and serves, among other things, to improve stability. The support body has a surface on which the stamp body is arranged, in particular in the center. The surface can be larger than the stamp surface.

In the following description, reference is often only made to one stamp body and support body, but it should be understood that this also applies equally to several stamp bodies and several support bodies.

In some aspects, the support body has a different material than the stamp body. In this context, a material can be used for the support body which has a higher rigidity than the material of the stamp body. The support body can be transparent in order to be able to check the transfer or the result of the transfer process from the support body.

In some aspects, the support body is at least partially covered with the material of the stabilizing layer, particularly on the side surfaces. On the one hand, this allows for a possibly simpler production or enables further functionalities to be accommodated here.

The material of the stamp body can be a plastic that is softer than the stabilizing material. Possible materials are based on PDMS, for example. Various components can be used as the material of the stabilizing layer. Among other things, a coating of SiO₂ or graphite has proven to be useful. In some other aspects, a metal can also be used, which is applied as a thin layer on the side surfaces, for example by electroplating or vapor deposition. Metals are conductive, which may make further functionalities possible. Suitable metals include Ag, Au, Ni, Ti or Pt. Compositions such as TiN are also possible. In some further aspects, the material of the side surfaces of the stamp can be (pre-)treated with a plasma so that the surface is chemically/physically modified. Thus, in some aspects, vitrification or oxidation of the surface of the side faces can take place.

One aspect is the thickness of the stabilizing layer. The layer should be thick enough to generate the necessary mechanical stiffness against shear forces. It has been found that the thickness should tend to increase with smaller edge lengths in order to ensure the necessary rigidity. In some aspects, it is therefore proposed that the thickness of the stabilizing layer is in the range between 1/1000 to 1/50, in particular between 1/800 to 1/100 and in particular 1/700 and 1/200 of an edge length of the stamp face. In other words, the thickness of the stabilizing layer depends on the edge length of the stamp surface. For edge lengths smaller than 10 μm, in some aspects the thickness of the layer is in the range of a few 10 nm, for example between 20 nm and 90 nm. In some aspects, the thickness is thus between 5 nm and 100 nm, in particular between 10 nm and 75 nm and in particular between 20 nm and 50 nm.

The material of the stabilizing layer can also influence the required thickness. For example, SiO₂ can generally have a smaller thickness than layers made of metal. In some aspects, a stamp surface has an edge length in the range between 2 μm and 50 μm. In particular, this can be between 2 μm and 30 μm and in particular less than 10 μm. For example, with an edge length of 10 μm, a length of the stamp is in the range of 13 μm to 50 μm, in particular between 12 μm to 25 μm.

One aspect deals with the area near the stamp surface. This stamp surface itself basically remains free of the material of the stabilizing layer and therefore has a defined tackiness. As a result, components adhere primarily to the stamp surface, but no longer along the side surfaces as in conventional transfer stamps, so that tilting during placement due to deflection tolerances is reduced.

A further aspect is also the depositing force applied, which in some aspects leads to a slight compression of the stamp perpendicular to the stamp surface. In order to ensure contact of the stamp surface with the component to be transferred even in the event of slight compression or a thermal change in length, it can be provided in some aspects that a small end region along the side edges to the stamp surface remains free of the material of the stabilizing layer. In other words, the stabilizing layer is set back slightly from the stamp surface. Starting from the stamp surface, this free area can be between 1 nm and 30 nm and in particular in a range between 2 nm and 10 nm on the side surfaces.

Some aspects deal with the shape of the stamp body. For example, the stamp body can have the shape of a cuboid, with the height forming the longest edge of the cuboid. Alternatively, the side surfaces of the stamp body may taper towards the stamp surface. In some aspects, the stamp body thus forms a truncated pyramid. In other aspects, the stamp body forms a truncated cone.

Further aspects deal with a method for manufacturing a transfer stamp or a plurality of such stamps. In the proposed method, a support body with a stamp body is provided. The stamp body has a height and a stamp surface with an edge length, wherein a ratio of the height to the edge length is greater than 1.3 and in particular greater than 2. The method also comprises forming a stabilizing layer, at least on side surfaces of the stamp body, wherein the stamp surface remains free of the stabilizing layer and a material of the stabilizing layer has a greater rigidity than a material of the stamp body.

Depending on the configuration and any design requirements, the stabilizing layer can be created by covering the stamp surface, e.g. with a small plate, a dummy semiconductor body or similar. The cover should be at least as large as the stamp area in order to cover it completely. In some aspects, the cover can also be larger and thus protrude beyond the stamp surface. A metal, in particular Ag, Au, PT, Ni or Ti, can then be applied to at least the side surfaces of the stamp body. Graphite can also be applied to the side surfaces of the stamp body. This can be done, for example, by electroplating, vapor deposition, sputtering or deposition.

In some aspects, the side surfaces can be treated with plasma. Depending on the material of the stamp body, this can trigger physical or chemical reactions, which in turn lead to a stabilizing and more rigid layer. In some aspects, the surface can be cured to form the stabilizing layer. Glazing is also possible, i.e. applying or creating a glass on the surface. In some aspects, this is SiO₂.

Depending on the embodiment, the cover applied to the stamp surface causes shading. In this way, the stabilizing layer is not produced right up to the edge of the stamp surface, but areas of the side surfaces of the stamp body adjacent to the stamp surface remain free of the material of the stabilizing layer. These areas remaining free of material at the upper edge can have a height of 1 nm to 30 nm and in particular between 2 nm and 10 nm starting from the upper edge in the direction of the support body.

In some aspects, the step of providing a support body with a stamp body comprises providing the support body with a depositing surface, providing a stamp body with a stamp surface, and attaching the stamp body to the support body. The support body and stamp body can be made of the same material, but can also be made of different materials. In particular, the support body can be made of a stiffer material than the stamp body. Alternatively, they can also be made from one piece.

An adhesive can be used to attach the stamp body to the support body. However, it is also possible to activate the surfaces to be joined, for example by plasma treatment. The stamp body can then be placed on the activated depositing surface. In some aspects, the surfaces are brought together in such a way that the depositing surface of the support body is brought into contact with a flat material reservoir and then these are moved away from each other again.

As a result, a material forming the stamp body is torn out or removed from a material reservoir. Predetermined breaking points can be provided to simplify this process. It is useful here if the stamp material is softer or more elastic than the material of the support body. In some aspects, an additional release layer can also be provided between the material reservoir and a temporary support so that the stamp material releases from the reservoir in a desired shape. For this purpose, it is also possible to structure the temporary carrier and then prepare it with the material reservoir. In this way, a material of the stamp body can be provided on a temporary carrier in recesses provided for this purpose. A release layer can be provided for easier removal.

In some aspects, the stamp body is provided on a temporary carrier whose adhesive force to the stamp body is lower than an adhesive force between the surface of the support body and the stamp body. This allows the support body and the stamp body to be manufactured separately and then joined together.

### BRIEF DESCRIPTION OF THE DRAWINGS

Further aspects and embodiments according to the proposed principle will become apparent with reference to the various embodiments and examples described in detail in connection with the accompanying drawings.

FIG. 1 shows a perspective view of a transfer stamp with some aspects according to the proposed principle;

FIGS. 2A to 2C illustrate various process steps for manufacturing a transfer stamp according to some aspects according to the proposed principle;

FIGS. 3A to 3D show a further embodiment of a method for generating a transfer stamp according to some aspects of the proposed principle;

FIGS. 4A to 4C illustrate a further embodiment of a method for generating a transfer stamp according to some aspects of the proposed principle; and

FIGS. 5A and 5B show steps of another embodiment of a method for generating a transfer stamp according to some aspects of the proposed principle.

### DETAILED DESCRIPTION OF ILLUSTRATIVE EMBODIMENTS

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects have a regular structure or shape. It should be noted that slight deviations from the ideal shape may occur in practice without, however, contradicting the inventive concept.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. It is thus possible to deduce such relationships between the elements on the basis of the figures.

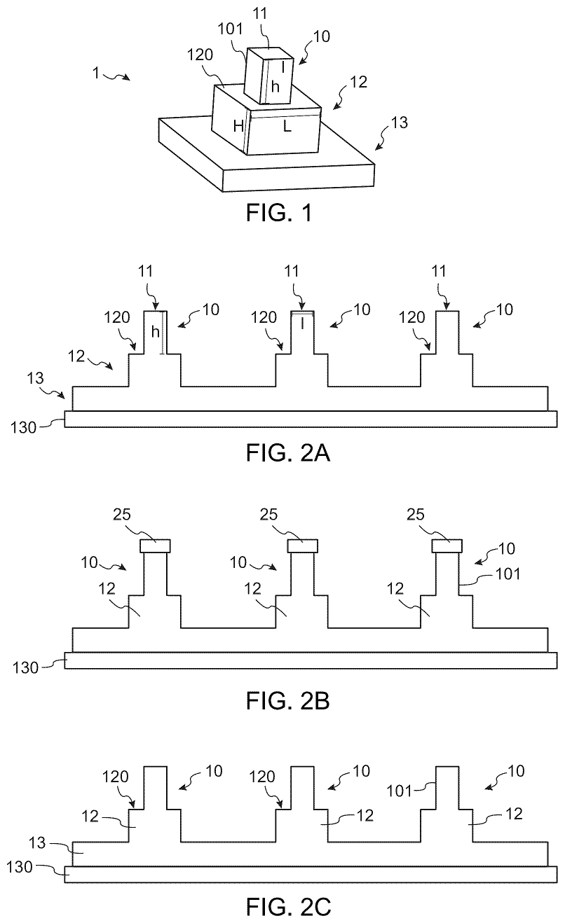

FIG. 1 shows an embodiment of a transfer stamp according to the proposed principle. The transfer stamp is mounted on an elastomeric carrier 13 and essentially comprises, in addition to the base body 13, a support body 12 and a stamp body 10 arranged on the support body. In this embodiment example, the support body 12 is square with a height H and a surface length L. The length L and height H are selected in such a way that the support body 12 is mounted at a sufficiently large distance from neighboring support bodies 12 so that during a transfer of components and, in particular, a shearing movement required for this purpose, the support bodies 12 do not interact with the semiconductor components to be transferred.

A stamp body 10 is arranged centrally on the surface 120 of the support body 12. This also comprises a square base surface, which forms the stamp surface 11 on the upper side. The material of the stamp body 10 is PDMS, although another plastic is also suitable. If necessary, the elastomeric material PDMS can also contain additives that change the elasticity or stiffness. The edge length 1 of the stamp surface 11 is smaller than the height h of the stamp body 10, so that a ratio of h to the edge length 1 is greater than 1 (h/l>1) and is, for example, in the range of 1.5 to 2.5 as shown here. The actual stamp surface is located on the upper side of the stamp body 10, which interacts with the semiconductor component to be transferred and for this purpose has a slightly sticky surface with respect to the material of the semiconductor components.

According to the proposed principle, the side surfaces of the stamp body 10 are now covered with a stabilizing layer 101. This is applied to the side surfaces of the stamp body 10 and has a rigidity which is greater than a rigidity of the elastomeric material of the stamp body 10. The stabilizing layer 101 is applied to the side surfaces of the stamp body 10 in particular in the form of a thin coating.

In other words, the stabilizing material applied to the side surfaces of the stamp body 10 is less elastic and prevents or reduces bending of the stamp body 10 during a shearing movement during the depositing or removal process of the semiconductor bodies.

In this way, the height h of the stamp body 10 can be increased without the shear forces occurring during the removal or depositing of the semiconductor bodies leading to damage to the stamp body or neighboring transfer stamps interfering with each other. The greater height h also ensures a greater distance between the semiconductor components and the support body 12 during the removal process, so that any misalignment of the stamp bodies during the transfer process has less of an effect. In particular, the greater height h of the stamp body 10 ensures that the support body 12 does not inadvertently interact with the semiconductor component.

The material 101 on the side surfaces of the support body can also extend to the surface 120 as well as the side surface of the support body 12 and the surface of the base 13. In embodiments, this material can be vapor-deposited, sputtered or otherwise applied to the surface of the transfer die shown in FIG. 1 during manufacture of the transfer die. The thickness of the applied material 101 is selected in such a way that sufficient rigidity is achieved depending on the material of the stamp body 10.

The thickness required for this therefore depends on the material of the stamp body 10 and its mechanical or elastic properties, but also on the properties of the applied material itself. Examples of such materials would be silicon dioxide SiO₂, which is applied to the side surfaces in the form of a glazing material 101. The thickness of silicon dioxide SiO₂ is in the range of a few nanometers to a few tens of nm. Alternative materials for application with increased rigidity with regard to the material of the stamp body 10 would also be graphite or various metals. The latter also have the advantage that they are electrically conductive, so that unintentional electrostatic charges can be avoided during the transfer. Possible materials for metals include silver, gold, platinum, but also titanium or nickel.

FIGS. 2A to 2C show various process steps for the manufacture of transfer stamps 1 according to the proposed principle.

In FIG. 2A, the material of the transfer stamp is applied to a transparent solid base 130 and is already structured accordingly. Each transfer stamp 1 comprises a support body 12 and a stamp body 10 arranged on the support body. The support body 12, stamp body 10 and also the base material 13 are manufactured from a single piece and comprise an elastic plastic, for example PDMS Sylgard 184®. This material has a slight tackiness with respect to the semiconductor materials to be transferred, so that the semiconductor components adhere well to the stamp pad when they come into contact with the stamp surface 11 and can be removed from a carrier.

As shown in FIG. 2A, the height h of the stamp body 10 is significantly greater than the corresponding edge length 1 of the stamp surface 11. The ratio of height h to edge length is in the range of 2 to 3 in this embodiment example.

A cover 25, for example a plate of semiconductor material, is now applied to the stamp surface 11 to protect the stamp surface before the further process steps, so that the exposed stamp surface 11 is completely covered. Then, as shown in FIG. 2B, the side surfaces of the stamp body 10 as well as the support body 12 and the surface of the base 13 are covered with a stabilizing material 101. The stabilizing layer 101 is applied in particular in the form of a thin coating to the side surfaces of the stamp bodies 10, so that areas between the stamp bodies 10 or support bodies remain free of the stabilizing material 101. Accordingly, the stabilizing material 101 does not fill the spaces between the stamp bodies, but merely covers the side surfaces of the stamp bodies 10.

As already mentioned, this material has a higher rigidity than the plastic used for the stamp body 10. The thickness of the applied material is in the range of approx. 20 nm to 100 nm and depends, among other things, on the edge length I of the stamp surface. In general, the thickness of the material of the stabilizing layer should also increase with larger ratios of h/l. The protection applied to the stamp surface 11 prevents the stabilizing material 101 from being deposited on the stamp surface. The cover on the stamp surface 11 in FIG. 2C is then removed again so that the stamp surface is now exposed.

During the deposition of the material 101 on the side surfaces, in some aspects the protection 25 applied to the stamp surface 11 may protrude slightly beyond the edge of the stamp surface. On the one hand, this is useful in order to reduce any misalignment, i.e. the effect of a slightly offset application of the cover 25 to the surface 11 or slippage during the process operation. On the other hand, a protruding area of the cover 25 creates a shadow along the end areas of the side surfaces, i.e. the areas adjacent to the stamp surface. As a result, less stabilizing material or even no stabilizing material is applied in this area, so that an edge or an edge area of the side surfaces near the stamp surface 11 remains free of the stabilizing material.

Put simply, the height h of the stamp body exceeds the height of the stabilizing side surfaces by a small amount in the range of a few nanometres to a few tens of nm. Or the stabilizing material is set back slightly by this amount. This has the advantage that a slight compression of the stamp surface when the stamp surface is pressed against the semiconductor components does not lead to contact between the stabilizing side surfaces and the semiconductor component. As a result, the adhesive force of the stamp surface 11 on the semiconductor components can be increased without the stabilizing side surfaces coming into contact with the semiconductor component and possibly damaging it. The finished embodiment of a transfer stamp shown in FIG. 2C can be used for a multiple transfer of elements.

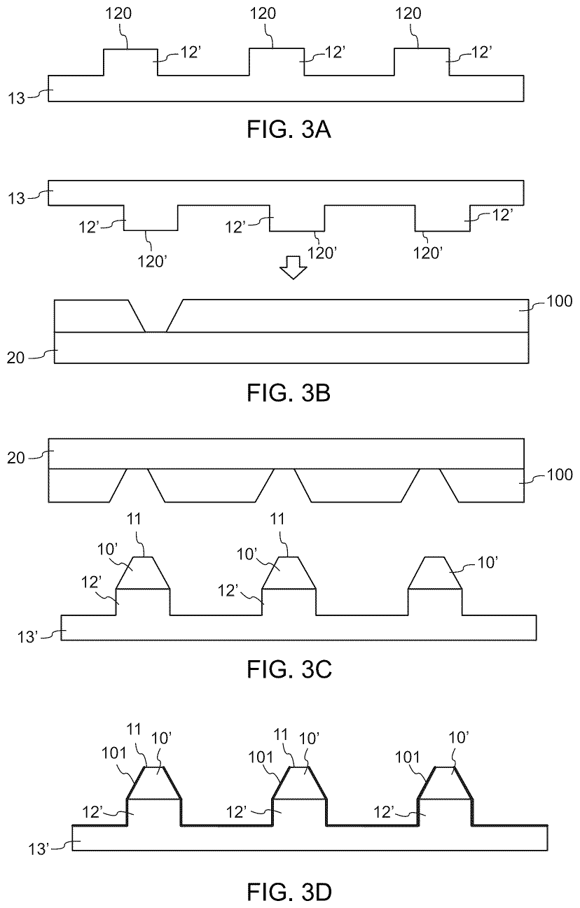

FIGS. 3A to 3D show a further embodiment of the manufacturing of transfer stamps according to the proposed principle. In this embodiment, a stamp base body is provided with the base 13 and support bodies 12′ applied to it. The support body 12′ and the base 13 comprise a material which has a significantly higher hardness and rigidity compared to the later material of the stamp body 10. In the next step, shown in FIG. 3B, the surface 120 of the support body 12′ is subjected to a plasma process so that the surface is activated. The activation of the surface creates free bonds that enable particularly good adhesion of a second, significantly softer layer 100, which is attached to a temporary carrier 20 as a material reservoir.

As shown in the embodiment example in FIG. 3B, the plasma-activated surface 120′ is now arranged facing the surface of the material 100 and pressed firmly onto it. In addition, the surface of the softer material reservoir for the stamp body 100 can also be activated with a corresponding plasma process. After pressing the surface 120′ onto the surface of the reservoir 100, they adhere to each other and the plasma-activated surface(s) stick together. The support bodies 12′ are then removed again so that part of the material of the stamp body 100 detaches, leaving a structure 10′ forming a truncated pyramid as a stamp body on the surface of the support body 12′. The truncated pyramid-shaped structure 10′ is relatively firmly connected to the support body 12′ and can be provided for the subsequent transfer of components by means of further processes.

Depending on the process design, a truncated cone-shaped structure can also be formed here.

In a subsequent step, the stamp surfaces of the structures 10′ are again covered with a cover as protection and then the stabilizing material 101 is applied to the side surfaces of the stamp bodies 10′ and the support bodies 12′. The resulting structure is then shown in FIG. 3D. The stabilizing layer 101 is applied to the side surfaces of the structures 10′ and the support bodies 12′, in particular in the form of a thin coating, so that areas between the structures 10′ or support bodies remain free of the stabilizing material 101. Accordingly, the stabilizing material 101 does not the spaces between the stamp bodies and the support bodies 12′, but merely covers the side surfaces of the stamp bodies 10′ and the support bodies 12′.

In this embodiment example, the diameter of the stamp bodies 10′ tapers towards the stamp surface 11 so that they form a truncated pyramid or a truncated cone. The resulting stamp is different from the previous embodiment, in which the edge length remains essentially the same over the height and the stamp bodies are made up of cuboid structures.

The embodiment shown in FIGS. 3A to 3C with different materials for the support body 12 and the stamp body 10 can also be varied in order to realize different designs adapted to the components to be transferred.

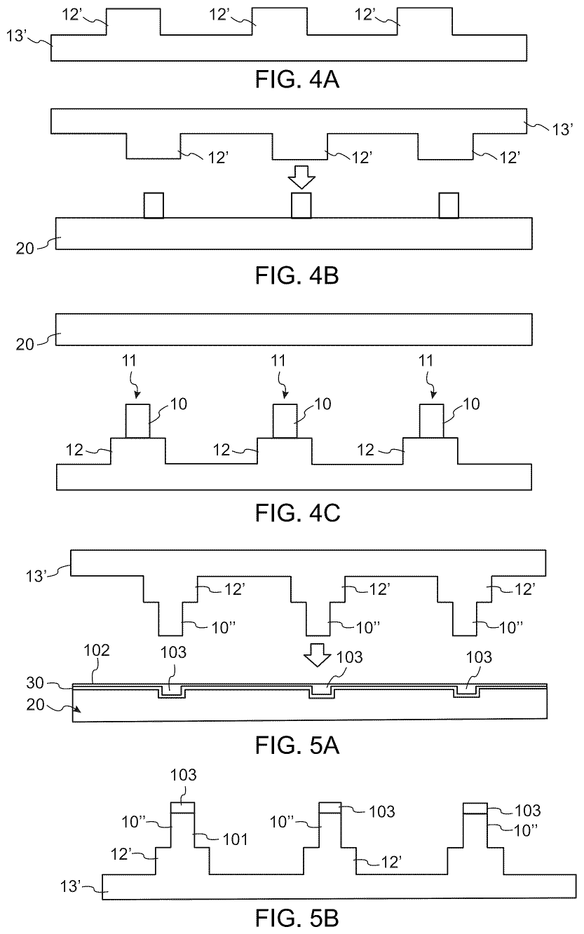

FIGS. 4A to 4C show some process steps for the manufacture of a large number of transfer stamps according to the proposed principle. In FIG. 4A, a base body 13′ with a support body 12′ is again provided, which is activated on its surfaces via a plasma process in FIG. 4B. Similarly, a temporary carrier 20 is prepared with several cuboidal stamp bodies 10, the surfaces of which are also activated by the plasma process.

The distance between the individual stamp bodies 10 corresponds to the distance between the centers of the respective support bodies 12′. Carrier 20 and base body 13′ with the respective elements are arranged opposite each other and the surfaces of the stamp bodies 10 are connected to the support bodies 12. After removing the glass carrier 20, the stamp bodies 10 thus remain on the support bodies 12 and can be subjected to the stabilizing material via the further process steps. In this way, for example, the embodiment shown in FIG. 1 can be realized.

FIGS. 5A and 5B show a further embodiment and transfer stamps. In FIG. 5A, a base body is provided which, in addition to the base 13′ and the support bodies 12′, also has centrally arranged stamp bodies 10″. The material of the stamp bodies 10″ is the same as the material of the support bodies 12′, the edge length at the top or bottom of the stamp bodies 10″ is significantly less than the corresponding height up to the support body 12′. This also creates a ratio of height to edge length that is greater than 1 and is between 2 and 3 in the present case.

This arrangement is now arranged opposite a structured glass substrate 20. The structured glass substrate 20 comprises a plurality of recesses at regular intervals, in which a release layer 30 and a soft elastomer material 103 present therein are introduced. The plasma-activated surface of the stamp body 10″ is now introduced into the recesses so that the material 103 bonds with the surface, making it easier to remove the material from the recesses through the release layer 30 after removal.

Detachment occurs due to the elastomer material 103 tearing off at the edges of the recesses. In an alternative embodiment, the glass substrate 20 is designed in such a way that the release layer 30 is only located at the bottom of the indentations and at their side edges. The soft elastomer layer introduced is then brought into contact with the plasma-activated surface of the stamp body 10″ and thus bonded. When moving away, the elastomer layer in the recess detaches slightly and tears at the side edges. Additional structuring of the detachment layer to match the indentations therefore provides a further improvement and results in defined stamps made of soft elastomer material.

In this way, small elastomeric stamp pads 103 made of softer PDMS material are formed on the upper side of the stamp body 10″. After removing the stamp pads 103, the side surfaces of the stamp pad 103, the side surfaces of the remaining body 10″ and the support body 12′ are then coated with a stabilizing material. The transfer stamp produced in this way is shown in FIG. 5B.

In the claims:

1-16. (canceled)

17. A transfer stamp comprising:
a plurality of stamp bodies, each having a height and a stamp surface with an edge length, wherein a ratio of the height to the edge length is greater than 1.3;
a stabilizing layer of a material different from the stamp body on sides of the stamp body, wherein the stamp surface remains substantially free of the material of the stabilizing layer, and wherein the material of the stabilizing layer has a greater stiffness than a material of the stamp body; and
a plurality of support bodies, each support body adjoining one of the stamp bodies in a longitudinal direction, wherein the support body has a surface on which the stamp body is arranged, the surface being larger than the stamp surface.

18. The transfer stamp according to claim 17, wherein the support bodies comprise a different material than the stamp bodies, and wherein the support bodies comprise a material with a higher rigidity than the material of the stamp bodies.

19. The transfer stamp according to claim 17, wherein side surfaces of the support bodies are covered with the material of the stabilizing layer.

20. The transfer stamp according to claim 17, wherein the material of the stabilizing layer comprises at least one material selected from the following group consisting of SiO₂, graphite, a metal and TiN.

21. The transfer stamp according to claim 17, wherein a thickness of the stabilizing layer is between 1/1000 and 1/50, inclusive, of the edge length of the stamp surface, and/or is between 5 nm and 100 nm, inclusive.

22. The transfer stamp according to claim 17, wherein a stamp surface has an edge length in a range between 2 μm and 50 μm, inclusive.

23. The transfer stamp according to claim 17, wherein regions of side surfaces of the stamp bodies adjacent to the stamp surface are free of the material of the stabilizing layer.

24. The transfer stamp according to claim 17, wherein side surfaces of the stamp body taper towards the stamp surface.

25. A method for manufacturing a transfer stamp, the method comprising:
providing a plurality of support bodies, each support body having a stamp body having a height and a stamp surface with an edge length, wherein a ratio of the height to the edge length is greater than 1.3; and
forming a stabilizing layer at least on side surfaces of the stamp bodies, wherein the stamp surfaces remain free of the stabilizing layer, wherein a material of the stabilizing layer has a greater rigidity than a material of the stamp bodies.

26. The method according to claim 25, wherein forming the stabilizing layer comprises:
covering the stamp surfaces with a cover; and
performing at least one of the following steps:
depositing a metal on at least the side surfaces of the stamp bodies;
depositing graphite on at least the side surfaces of the stamp bodies;
treating at least the side surfaces of the stamp bodies with a plasma; or
glazing at least the side surfaces of the stamp bodies.

27. The method according to claim 26, wherein the cover is a platelet.

28. The method according to claim 26, wherein, after forming the stabilizing layer, regions of the side surfaces of the stamp bodies adjacent to the stamp surface remain free of the material of the stabilizing layer starting from the stamp surface in a range from 1 nm to 30 on the side surfaces.

29. The method according to claim 25, wherein providing the plurality of support bodies comprises:
providing each support body with a deposition surface;
providing the plurality of stamp bodies with a stamp surface; and
attaching the stamp bodies to the support bodies.

30. The method according to claim 29, wherein attaching the stamp bodies to the support bodies comprises:
treating the deposition surfaces and a surface opposite the stamping surfaces; and
bringing together the treated deposition surfaces and the surfaces opposite the stamp surfaces, wherein optionally a material forming the stamp bodies is torn out of a material reservoir by moving away the support bodies.

31. The method according to claim 25, wherein the stamp bodies are provided on a temporary carrier whose adhesive force to the stamp bodies is less than an adhesive force between the surfaces of the support bodies and the stamp bodies.

32. The method according to claim 25, wherein a material of the stamp bodies is provided on a temporary carrier in recesses, and wherein the temporary carrier optionally comprises a release layer.

33. The method according to claim 25, wherein a material of the support bodies is different from the material of the stamp bodies, wherein the material of the support bodies has a higher stiffness than the material of the stamp bodies.
